(19) United States
(12) Patent Application Publication
(10) Pub. No.: US 2025/0321059 A1
(43) Pub. Date: Oct. 16, 2025

(54) MULTIPLE WICK SECTION HEAT PIPE

(71) Applicant: Cisco Technology, Inc., San Jose, CA (US)

(72) Inventors: Albert W. Chan, San Jose, CA (US); Don Nguyen, Santa Clara, CA (US); Glen Michael James Brooks, San Jose, CA (US)

(21) Appl. No.: 19/247,308

(22) Filed: Jun. 24, 2025

Related U.S. Application Data
(62) Division of application No. 18/155,850, filed on Jan. 18, 2023.

(51) Int. Cl. F28D 15/04; F28D 21/00; F28F 1/06; H01L 23/427

(52) U.S. Cl. CPC F28D 15/046; F28D 21/00; H01L 23/427; F28D 2021/0029; F28F 1/06

(57) ABSTRACT

A heat pipe provides effective heat transfer. In one example, a heat pipe includes an evaporator section, a condenser section, and a fluid transport section. The evaporator section includes a first wick having a first porosity. The condenser section includes a second wick having a second porosity. The fluid transport section is configured to transport a fluid between the evaporator section and the condenser section.

### CROSS-REFERENCE TO RELATED APPLICATIONS

This application is a divisional of U.S. patent application Ser. No. 18/155,850, filed Jan. 18, 2023, the entire contents of which are incorporated herein by reference.

### TECHNICAL FIELD

The present disclosure relates to heat pipes, and in particular to heat pipes with multiple wick sections to enhance heat transfer.

### BACKGROUND

A heat pipe is a device that can transfer heat from a heat source to a heat sink. Often, heat pipes are constructed from a copper tube with sintered porous copper wick lining the inside surface of the tube. The tube is evacuated, water is added to saturate the wick structures and the tube is sealed. Other working fluid besides water can be used. Heat pipes have numerous applications in thermal management, such as cooling of electronics and computer systems, spacecraft, energy devices, etc.

### BRIEF DESCRIPTION OF THE DRAWINGS

FIG. 1A illustrates a system configured to transfer heat from a heat source to a heat sink via a heat pipe that has multiple wick sections, according to an example embodiment.

FIG. 1B illustrates a cross-section of the middle wick section with grooved capillaries for enhanced fluid transport through the heat pipe of FIG. 1A, according to an example embodiment.

FIG. 2 illustrates a heat pipe that includes a mesh layer on top of the multiple (e.g., three) wick sections, according to an example embodiment.

FIG. 3 illustrates a first method of manufacturing a heat pipe, according to an example embodiment.

FIGS. 4A-4E collectively illustrate a second method of manufacturing a heat pipe, according to an example embodiment.

FIGS. 5A and 5B collectively illustrate a third method of manufacturing a heat pipe, according to an example embodiment.

FIG. 6 illustrates a flowchart of a method for using a heat pipe, according to an example embodiment.

FIG. 7 illustrates a flowchart of a method for manufacturing a heat pipe, according to an example embodiment.

### DETAILED DESCRIPTION

### Overview

Provided herein is a heat pipe for effective heat transfer. The heat pipe has multiple wick sections. In one example embodiment, a heat pipe includes an evaporator section, a condenser section, and a fluid transport section. The evaporator section includes a first wick having a first porosity. The condenser section includes a second wick having a second porosity. The fluid transport section is configured to transport vapor from the evaporator section to the condenser section, and to return condensate from condenser to evaporator.

### Example Embodiments

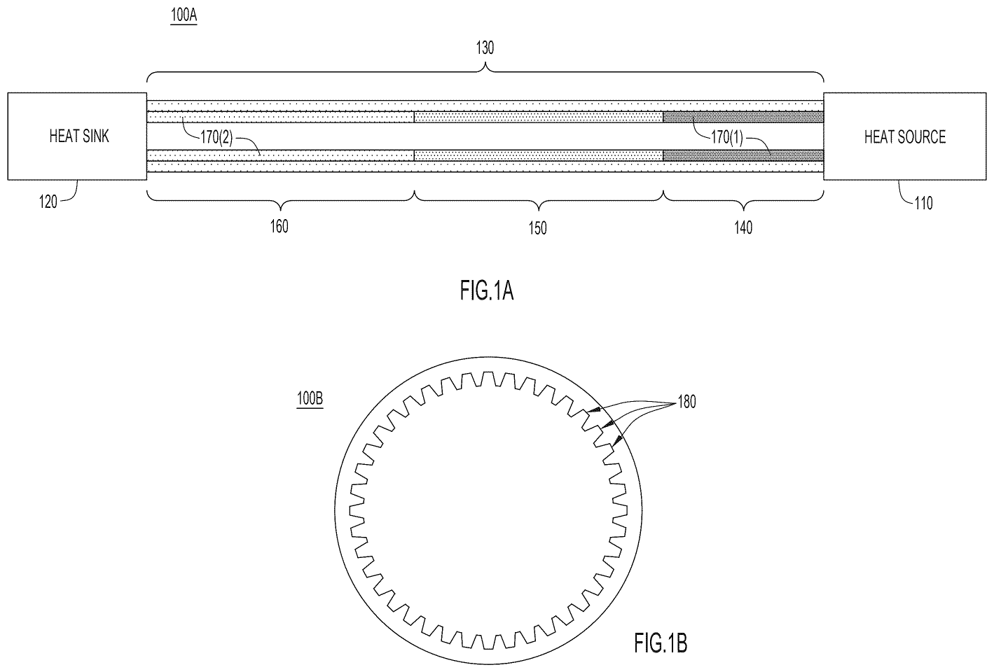

FIG. 1A illustrates a system 100A configured to transfer heat from heat source 110 to heat sink 120 via heat pipe 130, according to an example embodiment. Heat pipe 130 includes evaporator section 140, fluid transport section 150, and condenser section 160. Evaporator section 140 is in thermal communication with heat source 110, and condenser section 160 is in thermal communication with heat sink 120. Fluid transport section 150 connects evaporator section 140 and condenser section 160. In this example, heat pipe 130 is cylindrical, although it will be appreciated that, in general, a heat pipe provided in accordance with techniques described herein may be any suitable shape.

Fluid transport section 150 is configured to transport a working fluid (typically water) between evaporator section 140 and condenser section 160. In operation, liquid in evaporator section 140 extracts heat from heat source 110 and vaporizes. Heat pipe 110 may transport the vapor (and heat) from evaporator section 140 to condenser section 160 via fluid transport section 150. Upon reaching condenser section 160, the vapor condenses, transferring the heat to heat sink 120. Heat pipe 110 may transport the condensate from condenser section 160 to evaporator section 140 via fluid transport section 150. For this reason, fluid transport section 150 may also be referred to as a “condensate return section”, although there is a vapor space in the heat pipe core in the same region.

In one example, heat source 110 may be a networking component configured to generate heat. The networking component may include one or more Application-Specific Integrated Circuits (ASICs), Central Processing Units (CPUs), Graphics Processing Units (GPUs), etc. The networking component(s) may be used in networking servers, enterprise servers, optics integrated into silicon chip packages, etc. Thus, heat pipe 130 may provide additional heat sink options for increasing power dissipation (cooling) of modern ASICs.

Typical heat pipes experience a significant performance drop as heat pipe length increases. The longer a typical heat pipe, the lower the condensate return flow, and therefore the less effective that heat pipe is in cooling a heat source. This can be especially problematic for heat sinks that are remote from an evaporator (or cold plate) section. As a result, conventional heat pipes—particularly those used in remote heat pipe heatsink applications for cooling high power ASICs—are inherently limited in length.

In some examples, heat sink 120 may be a remote heat sink (e.g., remote from heat source 110), and the length of heat pipe 130 may be relatively large. To improve heat transfer from heat source 110 to heat sink 120—even with a relatively large heat pipe length—evaporator section 140 includes wick 170(1), and condenser section 160 includes wick 170(2). Wicks 170(1) and 170(2) may be disposed about the inner surfaces of evaporator section 140 and condenser section 160, respectively.

Wicks 170(1) and 170(2) may be sintered wicks (e.g., sintered mesh, sintered powder, etc.). The sintered wicks may provide relatively large surface areas for transferring heat: wick 170(1) may have a first porosity configured to provide a relatively large surface area for transferring heat to the working fluid in evaporator section 140, and wick 170(2) may have a second porosity configured to provide a relatively large surface area for transferring heat from the vapor to the heat pipe wall in condenser section 160.

The first and second porosities may be equal or unequal. In one example, the second porosity may be greater than the first porosity. In some examples, wick 170(2) may have a higher porosity than wick 170(1) because condenser section 160 may be longer than evaporator section 140. A higher-porosity wick has higher permeability, which increases condensate return flow. Thus, in these examples, wick 170(1) may be a fine wick configured to provide more surface area for heat transfer to the condensate, thereby increasing the rate of evaporation and heat removal from heat source 110, whereas wick 170(2) may be a coarser wick configured to provide a relatively high permeability to improve the condensate return rate to evaporator section 140. In one example, wick 170(1) may be a relatively fine wick constructed from lower-porosity sintered powder (e.g., particle size of approximately 100 microns), and wick 170(2) may be a relatively coarse wick constructed from higher-porosity sintered powder (e.g., particle size greater than 100 microns) and/or sintered mesh.

Wicks 170(1) and 170(2) may increase the cooling capacity of heat pipe 130, allowing for high performance (even when heat pipe 130 is relatively long) compared to typical heat pipes used for remote heat pipe heatsinks. This heat pipe design may ultimately improve flexibility in remote heat pipe heatsink configurations.

FIG. 1B illustrates a cross-section 100B of fluid transport section 150, according to an example embodiment. As shown, fluid transport section 150 may use capillary grooves 180 (e.g., grooved capillaries) that extend between evaporator section 140 and condenser section 160. Only three of the grooves are explicitly labeled for ease of viewing, but it will be appreciated that the term “grooves 180” may apply to all the grooves shown in cross-section 100B.

Grooves 180 are located on the inner surface of fluid transport section 150. Grooves 180 may be considered a type of wick structure, like wicks 170(1) and 170(2). A small wick pore size and large capillary pumping are desired, with capillary pumping capability proportional to its permeability. In one embodiment, grooves 180 may have the largest pore size of any heat pipe wick and a highest permeability. In an application where gravity exists, grooves may be preferable to other wicks in transporting condensate in the adiabatic section 150. In some examples, grooves 180 may extend beyond fluid transport section 150 into evaporator section 140 and/or condenser section 160.

Grooves 180 may preserve strong thermal performance of heat pipe 130, even when the distance between evaporator section 140 and condenser section 160 is large. Grooves 180 may have a higher permeability, and smaller surface area, than sintered wick. Grooves 180 may therefore provide a high condensate return flow rate, enabling grooves 180 to quickly transport the condensate from condenser section 160 to evaporator section 140. As a result, evaporator section 140 and condenser section 160 may have a large separation. Moreover, due to the relatively high condensate return flow rate, cooling capacity may be increased compared to typical remote heat pipe heatsinks.

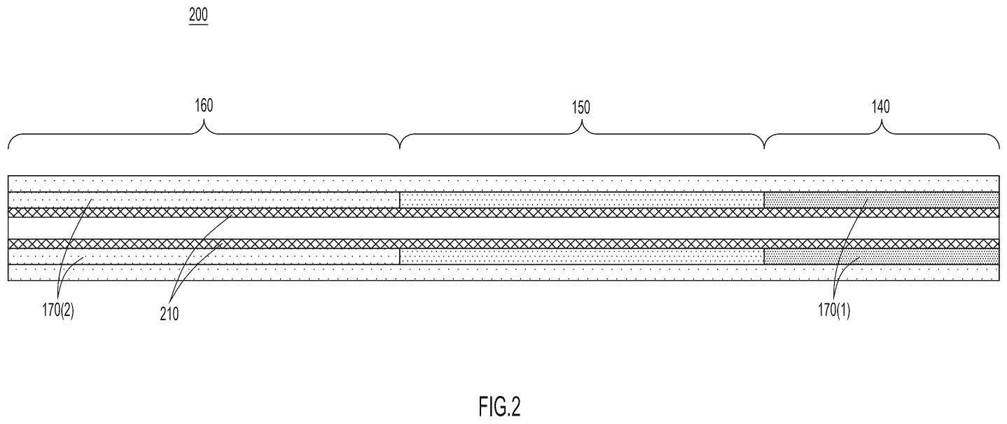

With continuing reference to FIGS. 1A and 1B, FIG. 2 illustrates heat pipe 200, which includes mesh layer 210, according to an example embodiment. Mesh layer 210 may be disposed on evaporator section 140, fluid transport section 150, and/or condenser section 160. In the specific example of FIG. 2, mesh layer 210 covers the entire inner surface of evaporator section 140, fluid transport section 150, and condenser section 160. Although heat pipe 200 is cylindrical, it will be appreciated that, in general, a heat pipe provided in accordance with techniques described herein may be any suitable shape.

Mesh layer 210 may shield the condensate from the (high) shear forces exerted by the vapor flowing from evaporator section 140 to condenser section 160. That is, because vapor flow velocity can be very high, the vapor can impede the returning condensate. Mesh layer 210 may protect the returning, underlying condensate from the vapor. Mesh layer 210 may also increase wick capacity. The benefits of mesh layer 210 may be especially pronounced if fluid transport section 150 includes grooves 180. Mesh layer 210 may enable heat pipe 130 to have a relatively large diameter without negatively impacting performance.

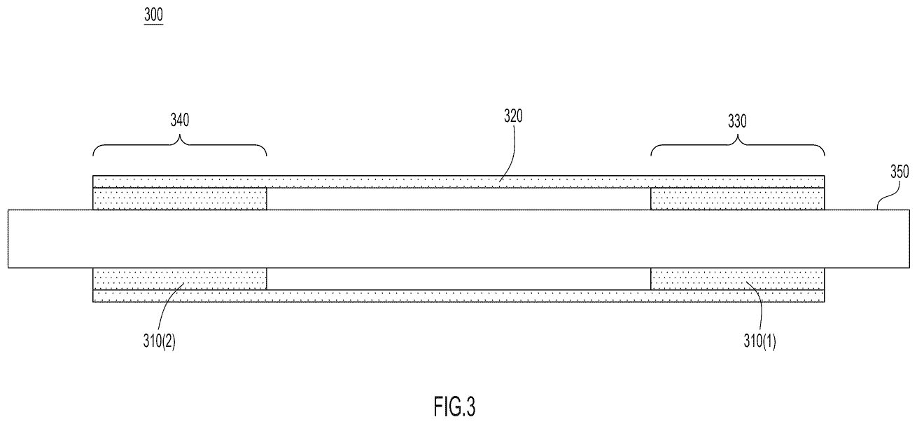

FIGS. 3, 4A-4E, and 5A and 5B illustrate three distinct methods for manufacturing/fabricating a heat pipe described herein. As discussed in greater detail below, all three methods involve providing a first preform in an evaporator section of a heat pipe structure and a second preform in a condenser section of the heat pipe structure, and producing, from the first preform and the second preform, a first wick having a first porosity at the evaporator section and a second wick having a second porosity at the condenser section.

With reference to FIG. 3, FIG. 3 illustrates a first method of manufacturing a heat pipe, according to an example embodiment. FIG. 3 depicts system 300, which includes preforms 310(1) and 310(2), heat pipe structure 320—which in turn includes evaporator section 330 and condenser section 340—and mandrel 350.

The first method may involve preparing preforms 310(1) and 310(2) outside heat pipe structure 320. For example, preforms 310(1) and 310(2) may be prepared from a Cu slurry that is mixed with a binder and a foaming agent and then dried to remove any liquid carrier. In this example, both preforms 310(1) and 310(2) and heat pipe structure 320 are cylindrical, although it will be appreciated that, in general, these components may be any suitable shape.

The first method may further involve aligning preform 310(1) in evaporator section 330 and preform 310(2) in condenser section 340. In one example, a dimension (e.g., diameter) of preform 310(1) may be less than a dimension (e.g., diameter) of evaporator section 330, and a dimension (e.g., diameter) of preform 310(2) may be less than a dimension (e.g., diameter) of condenser section 340. This may permit preforms 310(1) and 310(2) to be inserted into heat pipe structure 320. In one example, to enable the insertion and alignment of preforms 310(1) and 310(2), mandrel 350 may be inserted through preforms 310(1) and 310(2).

After aligning preform 310(1) in evaporator section 330 and preform 310(2) in condenser section 340, preforms 310(1) and 310(2) may be expanded to fit snugly inside heat pipe structure 320. In one example, preforms 310(1) and 310(2) may be expanded using heat to activate the foaming agent. After preforms 310(1) and 310(2) have been expanded, preforms 310(1) and 310(2), heat pipe structure 320, and/or mandrel 350 may be heated to a higher temperature to burn off organic materials. Then, preforms 310(1) and 310(2), heat pipe structure 320, and/or mandrel 350 may be heated to an even higher temperature to sinter preforms 310(1) and 310(2). The sintering may produce the first wick (e.g., wick 170(1)) having the first porosity at evaporator section 330 and the second wick (e.g., wick 170(2)) having the second porosity at condenser section 340. Mandrel 350 may be removed after sintering is complete.

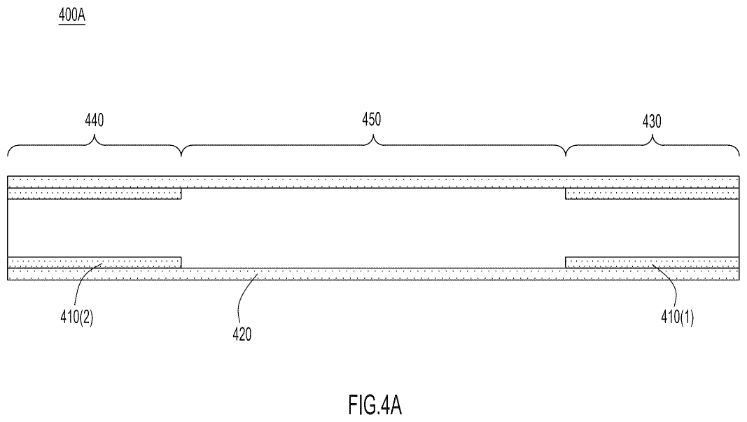

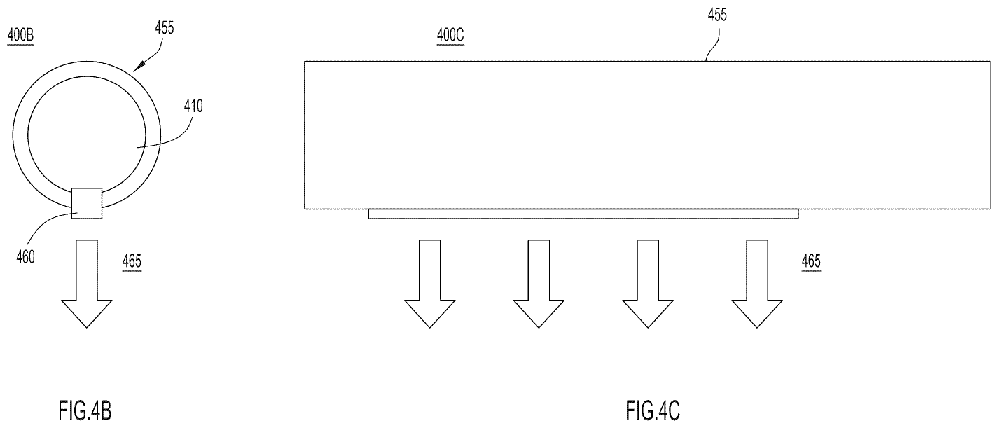

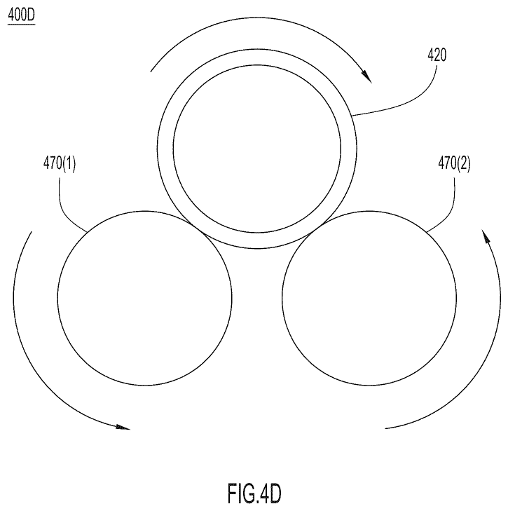

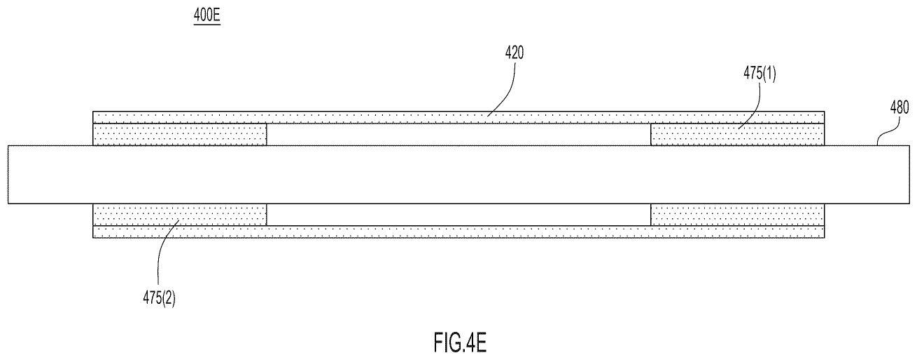

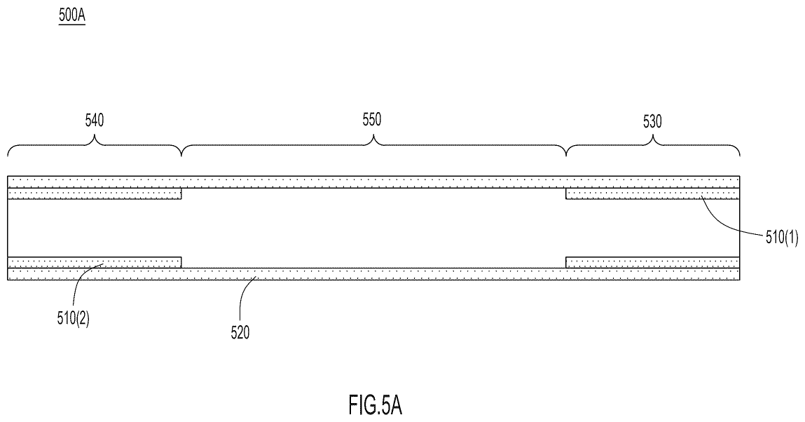

Turning now to FIGS. 4A-4E, FIGS. 4A-4E collectively illustrate a second method of manufacturing a heat pipe, according to an example embodiment. With reference first to FIG. 4A, FIG. 4A depicts system 400A, which includes slurry 410(1) and 410(2) and heat pipe structure 420. Slurry 410(1) and 410(2) may be a Cu powder slurry that includes a binder and a foaming agent. Heat pipe structure 420 includes evaporator section 430, condenser section 440, and fluid transport section 450. Fluid transport section 450 may define one or more grooves (e.g., grooved capillaries) that extend between evaporator section 430 and condenser section 440. In this example, heat pipe structure 420 is cylindrical, although it will be appreciated that, in general, heat pipe structure 420 may be any suitable shape.

The second method may involve depositing slurry 410(1) and 410(2) in evaporator section 430 and condenser section 440, respectively. For instance, slurry 410(1) and 410(2) may be deposited on either end of heat pipe structure 420.

FIGS. 4B and 4C illustrate a method for depositing slurry 410(1) and 410(2) in evaporator section 430 and condenser section 440. FIGS. 4B and 4C depicts respective cross-sectional views 400B and 400C of container 455. Container 455 may be configured to hold the slurry 410(1) and 410(2) (collectively referred to as “slurry 410”), and may define at least one hole (e.g., hole 460) through which slurry 410 may be dispensed. Hole 460 may be a dispensing gap that runs along an axial length of container 455.

Container 455 may be shaped to fit inside heat pipe structure 420. For instance, container 455 may be a hollow cylinder (e.g., a tube) with a diameter smaller than that of heat pipe structure 420. In one example, after slurry 410 is added to container 455, container 455 may be inserted into heat pipe structure 420. As illustrated by arrows 465, slurry 410 may be dispensed from container 455 via hole 460. Container 455 may dispense a fixed amount of slurry 410 (e.g., slurry 410(1) and 410(2)) at evaporator section 430 and condenser section 440. As a result, slurry 410(1) and 410(2) may also be referred to as “deposited layers.” In one example, container 455 may be separately introduced to both ends of heat pipe structure 420 to deposit slurry 410.

FIG. 4D depicts system 400D, which includes heat pipe structure 420 after slurry 410 has been deposited. System 400D further includes heated rollers 470(1) and 470(2). Heated rollers 470(1) and 470(2) may rotate and heat heat pipe structure 420. Rotating heat pipe structure 420 may distribute slurry 410 about heat pipe structure 420, evenly coating an interior/internal surface of heat pipe structure 420. Heating heat pipe structure 420 may dry slurry 410(1) and 410(2) to produce the first and second preforms (e.g., Cu powder cylinders). For example, the first and second preforms may be dry powder deposits that remain on the interior surface of heat pipe structure 420.

FIG. 4E depicts system 400E, which includes heat pipe structure 420, preforms 475(1) and 475(2), and mandrel 480. Preforms 475(1) and 475(2) may be produced from slurry 410(1) and 410(2) using system 400D (FIG. 4D). In one example, mandrel 480 may be inserted through preforms 475(1) and 475(2), and preforms 475(1) and 475(2) may be expanded to fit snugly inside the interior surface of heat pipe structure 420. In one example, preforms 475(1) and 475(2) may be expanded using heat to activate the foaming agent. After preforms 475(1) and 475(2) have been expanded, preforms 475(1) and 475(2), heat pipe structure 420, and mandrel 480 may be heated to a higher temperature to burn off organic materials. Then, preforms 475(1) and 475(2), heat pipe structure 420, and mandrel 480 may heated at an even higher temperature to sinter preforms 475(1) and 475(2). The sintering may produce the first wick (e.g., wick 170(1)) having the first porosity at evaporator section 430, and the second wick (e.g., wick 170(2)) having the second porosity at condenser section 440. Mandrel 480 may be removed after sintering is complete.

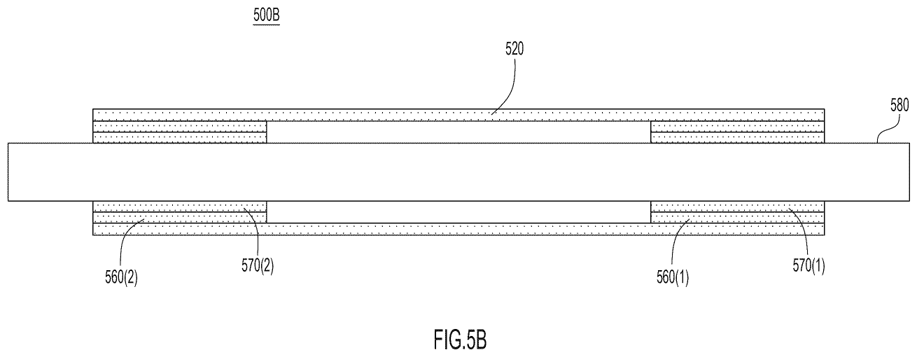

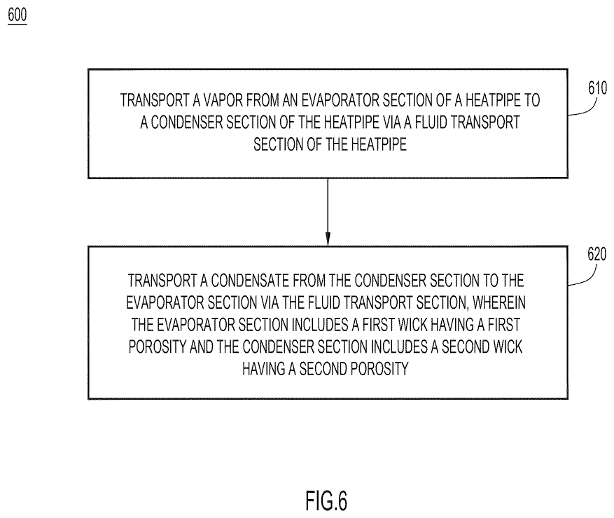

FIGS. 5A and 5B collectively illustrate a third method of manufacturing a heat pipe, according to an example embodiment. The third method may be a combination of the first method (FIG. 3) and the second method (FIGS. 4A-4E). With reference to FIG. 5A, FIG. 5A depicts system 500A, which includes slurry 510(1) and 510(2) and heat pipe structure 520. Heat pipe structure 520 includes evaporator section 530, condenser section 540, and fluid transport section 550.

The third method may involve depositing slurry 510(1) and 510(2) in evaporator section 530 and condenser section 540 and drying slurry 510(1) and 510(2) to form a first preform layer (e.g., a thin layer) in evaporator section 530 and a second preform layer (e.g., another thin layer) in condenser section 540. Slurry 510(1) and 510(2) may be deposited and dried as discussed above in connection with FIGS. 4B-4D (e.g., using a container and/or heated rollers).

FIG. 5B depicts system 500B, which includes heat pipe structure 520, preform layers 560(1) and 560(2), preform components 570(1) and 570(2), and mandrel 580. Preform layers 560(1) and 560(2) may be prepared as discussed above in connection with FIG. 5A. The third method may also involve preparing preform components 570(1) and 570(2) outside heat pipe structure 520. Preform components 570(1) and 570(2) may be prepared as discussed above in connection with FIG. 3.

Preform component 570(1) may be aligned with preform layer 560(1) in evaporator section 530, and preform component 570(2) may be aligned with preform layer 560(2) in condenser section 540. For example, preform components 570(1) and 570(2) may be inserted into either end of heat pipe structure 520, over the surfaces occupied by preform layers 560(1) and 560(2). Mandrel 580 may be inserted into preform components 570(1) and 570(2) to hold preform components 570(1) and 570(2) in place.

The third method further involves forming the first preform from preform layer 560(1) and preform component 570(1), and the second preform from preform layer 560(2) and preform component 570(2). The first and second preforms may be formed as discussed above in connection with FIGS. 3 and 4E (e.g., heating to activate the foaming agent, burning off organic materials, sintering, etc.).

The first, second, and third methods may be modified to fabricate a heat pipe that includes a mesh (FIG. 2). To integrate a mesh into a heat pipe, the mesh may be wrapped around the mandrel (mandrels 350, 480, 580) before the mandrel is inserted into the heat pipe structure. When heated (e.g., sintered), the mesh may attach to the preform, preform component, and/or heat pipe structure, and the mandrel may then be removed, leaving the mesh behind.

FIG. 6 illustrates a flowchart of a method 600 for using a heat pipe, according to an example embodiment. At operation 610, a vapor is transported from an evaporator section of a heat pipe to a condenser section of the heat pipe via a fluid transport section of the heat pipe. At operation 620, a condensate is transported from the condenser section to the evaporator section via the fluid transport section. The evaporator section includes a first wick having a first porosity and the condenser section includes a second wick having a second porosity.

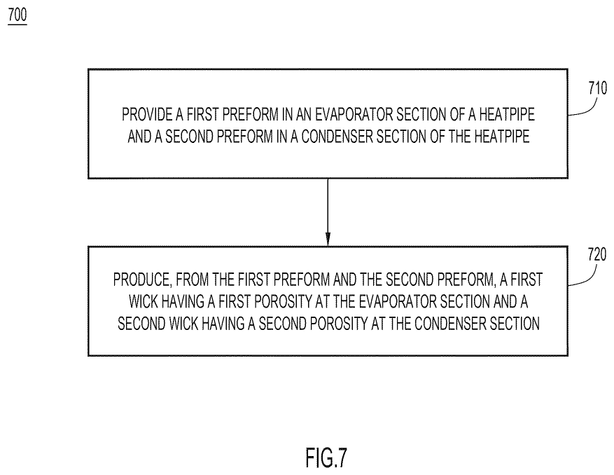

FIG. 7 illustrates a flowchart of a method 700 for manufacturing a heat pipe, according to an example embodiment. At operation 710, a first preform is provided in an evaporator section of a heat pipe and a second preform is provided in a condenser section of the heat pipe. At operation 720, a first wick having a first porosity is produced at the evaporator section from the first preform and a second wick having a second porosity is produced at the condenser section from the second preform.

Note that with the examples provided herein, interaction may be described in terms of one, two, three, or four entities. However, this has been done for purposes of clarity, simplicity and example only. The examples provided should not limit the scope or inhibit the broad teachings of systems, networks, etc. described herein as potentially applied to a myriad of other architectures.

Note that in this Specification, references to various features (e.g., elements, structures, nodes, modules, components, engines, logic, steps, operations, functions, characteristics, etc.) included in ‘one embodiment’, ‘example embodiment’, ‘an embodiment’, ‘another embodiment’, ‘certain embodiments’, ‘some embodiments’, ‘various embodiments’, ‘other embodiments’, ‘alternative embodiment’, and the like are intended to mean that any such features are included in one or more embodiments of the present disclosure, but may or may not necessarily be combined in the same embodiments.

Each example embodiment disclosed herein has been included to present one or more different features. However, all disclosed example embodiments are designed to work together as part of a single larger system or method. This disclosure explicitly envisions compound embodiments that combine multiple previously-discussed features in different example embodiments into a single system or method.

It is also noted that the operations and steps described with reference to the preceding figures illustrate only some of the possible scenarios that may be executed by one or more entities discussed herein. Some of these operations may be deleted or removed where appropriate, or these steps may be modified or changed considerably without departing from the scope of the presented concepts. In addition, the timing and sequence of these operations may be altered considerably and still achieve the results taught in this disclosure. The preceding operational flows have been offered for purposes of example and discussion. Substantial flexibility is provided by the embodiments in that any suitable arrangements, chronologies, configurations, and timing mechanisms may be provided without departing from the teachings of the discussed concepts.

As used herein, unless expressly stated to the contrary, use of the phrase ‘at least one of’, ‘one or more of’, ‘and/or’, variations thereof, or the like are open-ended expressions that are both conjunctive and disjunctive in operation for any and all possible combination of the associated listed items. For example, each of the expressions ‘at least one of X, Y and Z’, ‘at least one of X, Y or Z’, ‘one or more of X, Y and Z’, ‘one or more of X, Y or Z’ and ‘X, Y and/or Z’ can mean any of the following: 1) X, but not Y and not Z; 2) Y, but not X and not Z; 3) Z, but not X and not Y; 4) X and Y, but not Z; 5) X and Z, but not Y; 6) Y and Z, but not X; or 7) X, Y, and Z.

Additionally, unless expressly stated to the contrary, the terms ‘first’, ‘second’, ‘third’, etc., are intended to distinguish the particular nouns they modify (e.g., element, condition, node, module, activity, operation, etc.). Unless expressly stated to the contrary, the use of these terms is not intended to indicate any type of order, rank, importance, temporal sequence, or hierarchy of the modified noun. For example, ‘first X’ and ‘second X’ are intended to designate two ‘X’ elements that are not necessarily limited by any order, rank, importance, temporal sequence, or hierarchy of the two elements. Further as referred to herein, ‘at least one of’ and ‘one or more of’ can be represented using the ‘(s)’ nomenclature (e.g., one or more element(s)).

In one form, an apparatus is provided. The apparatus comprises: an evaporator section that includes a first wick having a first porosity; a condenser section that includes a second wick having a second porosity; and a fluid transport section configured to transport a fluid between the evaporator section and the condenser section.

In one example, the second porosity is greater than the first porosity

In one example, the fluid transport section defines one or more grooves that extend between the evaporator section and the condenser section.

In one example, the apparatus further comprises a mesh layer disposed on the fluid transport section.

In one example, the apparatus further comprises a mesh layer on at least one of the evaporator section and the condenser section.

In one example, the evaporator section is in thermal communication with a networking component configured to generate heat, and the condenser section is in thermal communication with a heat sink.

In another form, a method is provided. The method comprises: transporting a vapor from an evaporator section of a heat pipe to a condenser section of the heat pipe via a fluid transport section of the heat pipe; and transporting a condensate from the condenser section to the evaporator section via the fluid transport section, wherein the evaporator section includes a first wick having a first porosity and the condenser section includes a second wick having a second porosity.

In another form, another method is provided. The other method comprises: providing a first preform in an evaporator section of a heat pipe structure and a second preform in a condenser section of the heat pipe structure; and producing, from the first preform and the second preform, a first wick having a first porosity at the evaporator section and a second wick having a second porosity at the condenser section.

In one example, providing the first preform in the evaporator section and the second preform in the condenser section includes: preparing the first preform and the second preform outside the heat pipe structure; and aligning the first preform in the evaporator section and the second preform in the condenser section. In a further example, a dimension of the first preform is less than a dimension of the evaporator section and a dimension of the second preform is less than a dimension of the condenser section, the other method further comprising: after aligning the first preform in the evaporator section and the second preform in the condenser section, expanding the first preform and the second preform.

In one example, providing the first preform in the evaporator section and the second preform in the condenser section includes: depositing a slurry in the evaporator section and the condenser section; and drying the slurry to produce the first preform and the second preform. In a further example, depositing the slurry includes: inserting a container of the slurry into the heat pipe structure, wherein the container defines at least one hole; and dispensing the slurry from the container via the at least one hole. In a still further example, the other method further comprises: distributing the slurry about the heat pipe structure by rotating the heat pipe structure. In another further example, the other method further comprises: depositing the slurry in a fluid transport section of the heat pipe structure.

In one example, providing the first preform in the evaporator section and the second preform in the condenser section includes: depositing a slurry in the evaporator section and the condenser section; drying the slurry to form a first preform layer in the evaporator section and a second preform layer in the condenser section; preparing a first preform component and a second preform component outside the heat pipe structure; aligning the first preform component with the first preform layer in the evaporator section and the second preform component with the second preform layer in the condenser section; forming, from the first preform layer and the first preform component, the first preform; and forming, from the second preform layer and the second preform component, the second preform.

One or more advantages described herein are not meant to suggest that any one of the embodiments described herein necessarily provides all of the described advantages or that all the embodiments of the present disclosure necessarily provide any one of the described advantages. Numerous other changes, substitutions, variations, alterations, and/or modifications may be ascertained to one skilled in the art and it is intended that the present disclosure encompass all such changes, substitutions, variations, alterations, and/or modifications as falling within the scope of the appended claims.

What is claimed is:

1. A method, comprising:
forming a first preform from a first slurry;
forming a second preform from a second slurry;
producing a first wick having a first porosity from the first preform in an evaporator section of a heat pipe structure; and
producing a second wick having a second porosity from the second preform in a condenser section of the heat pipe structure.

2. The method of claim 1, wherein the first preform is formed from the first slurry and the second preform is formed from the second slurry outside of the heat pipe structure.

3. The method of claim 2, further comprising:
aligning and inserting the first preform in the evaporator section of the heat pipe structure after forming the first preform; and
aligning and inserting the second preform in the condenser section of the heat pipe structure after forming the second preform.

4. The method of claim 3, further comprising:
expanding the first preform and the second preform after inserting the first preform in the evaporator section of the heat pipe structure and inserting the second preform in the condenser section of the heat pipe structure.

5. The method of claim 4, further comprising:
heating the first preform and the second preform to a first temperature to expand the first preform and the second preform via a foaming agent contained in the first preform and the second preform; and
heating the first preform and the second preform to a second temperature, greater than the first temperature, to produce the first wick having the first porosity and the second wick having the second porosity.

6. The method of claim 1, further comprising:
depositing the first slurry in the evaporator section of the heat pipe structure and the second slurry in the condenser section of the heat pipe structure; and
drying the first slurry and the second slurry to form the first preform and the second preform within the evaporator section and the condenser section, respectively.

7. The method of claim 6, wherein depositing the first slurry and the second slurry comprises:
inserting a container having the first slurry and the second slurry into the heat pipe structure, wherein the container defines at least one hole; and
dispensing the first slurry and the second slurry from the container via the at least one hole to deposit the first slurry and the second slurry into the heat pipe structure.

8. The method of claim 7, further comprising:
rotating the heat pipe structure to distribute the first slurry about the evaporator section and to distribute the second slurry about the condenser section after dispensing the first slurry and the second slurry from the container into the heat pipe structure.

9. The method of claim 8, further comprising:
heating the first slurry and the second slurry while rotating the heat pipe structure to dry the first slurry and the second slurry.

10. The method of claim 6, further comprising:
heating the first preform and the second preform to a first temperature to expand the first preform and the second preform via a foaming agent contained in the first preform and the second preform; and
heating the first preform and the second preform to a second temperature, greater than the first temperature, to produce the first wick having the first porosity and the second wick having the second porosity.

11. The method of claim 6, further comprising:
aligning and inserting a third preform in the evaporator section of the heat pipe structure on the first preform;
aligning and inserting a fourth preform in the condenser section of the heat pipe structure on the second preform;
producing the first wick from the first preform and the third preform; and
producing the second wick from the second preform and the fourth preform.

12. A method, comprising:
drying a first slurry and a second slurry to remove liquid therein and form a first preform and a second preform; and
heating the first preform and the second preform in a heat pipe structure to produce a first wick having a first porosity and a second wick having a second porosity in the heat pipe structure.

13. The method of claim 12, further comprising:
mixing a binder and a foaming agent into the first slurry and the second slurry prior to drying the first slurry and the second slurry.

14. The method of claim 13, further comprising:
activating the foaming agent in the first preform and the second preform via heat to expand the first preform and the second preform in the heat pipe structure prior to producing the first wick and the second wick.

15. The method of claim 12, wherein the first slurry and the second slurry are dried outside of the heat pipe structure to produce the first preform and the second preform.

16. The method of claim 12, further comprising depositing the first slurry and the second slurry in the heat pipe structure, wherein the first slurry and the second slurry are dried after deposition in the heat pipe structure to form the first preform and the second preform in the heat pipe structure.

17. A method, comprising:
inserting a container having a slurry into a heat pipe structure;
dispensing the slurry from the container into the heat pipe structure via at least one hole formed in the container;
drying the slurry to form a preform in the heat pipe structure; and
heating the preform to produce a wick in the heat pipe structure.

18. The method of claim 17, wherein a first portion of the slurry is dispensed in an evaporator section in the heat pipe structure such that the preform is a first preform formed in the evaporator section and the wick is a first wick produced in the evaporator section, and the method further comprises:
dispensing a second portion of the slurry in a condenser section in the heat pipe structure;
drying the second portion of the slurry to form a second preform in the condenser section; and
heating the second preform to produce a second wick in the condenser section.

19. The method of claim 18, wherein inserting the container into the heat pipe structure comprising separately inserting the container in the heat pipe structure at the evaporator section and at the condenser section to dispense the first portion of the slurry in the evaporator section and the second portion of the slurry in the condenser section, respectively.

20. The method of claim 17, further comprising rotating the heat pipe structure with heated rollers to distribute the slurry dispensed in the heat pipe structure and dry the slurry to form the preform.
